(19) United States
(12) Patent Application Publication
(10) Pub. No.: US 2012/0138962 A1
(43) Pub. Date: Jun. 7, 2012

(54) LIGHT EMITTING DIODE PACKAGE

(75) Inventor: JIAN-SHIHN TSANG, Tu-Cheng (TW)

(73) Assignee: HON HAI PRECISION INDUSTRY CO., LTD., Tu-Cheng (TW)

(21) Appl. No.: 13/100,241

(22) Filed: May 3, 2011

(30) Foreign Application Priority Data
Dec. 1, 2010 (TW) 99141815

(51) Int. Cl. H01L 27/146

(52) U.S. Cl. 257/81; 257/E27.13

(57) ABSTRACT

A light emitting diode package includes a number of light emitting diode chips, a number of color sensor modules, and a reflecting cup around the light emitting diode chips. Each light emitting diode chip has a main light emitting surface and a sub light emitting surface opposite to the main light emitting surface. Intensities of light from the light emitting diode chips are detected by the color sensor modules for adjusting color temperatures of the light from the light emitting diode chips.

### BACKGROUND

1. Technical Field

The disclosure relates to light emitting diodes, and particularly to a light emitting diode package.

2. Description of the Related Art

Light emitting diodes' (LEDs) many advantages, such as high luminosity, low operational voltage, low power consumption, compatibility with integrated circuits, easy driving, long term reliability, and environmental friendliness have promoted their wide use as a light source. Now, LEDs are commonly applied in environmental lighting. It is well known that color temperature and intensities of LEDs are affected by variations in temperature of the LEDs. Thus, how to stabilize the color temperature and intensities of the light emitting diode are substantially important issues.

Therefore, it is desirable to provide an LED package which can overcome the described limitations.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present light emitting diode package. Moreover, in the drawings, like reference numerals designate corresponding parts throughout the views.

FIG. 1 is a cross section view of a light emitting diode package in accordance with a first embodiment.

FIG. 2 is a cross section view of a light emitting diode package in accordance with a second embodiment.

FIG. 3 is a cross section view of a light emitting diode package in accordance with a third embodiment.

### DETAILED DESCRIPTION

Embodiments of a light emitting diode (LED) package as disclosed are described in detail here with reference to the drawings.

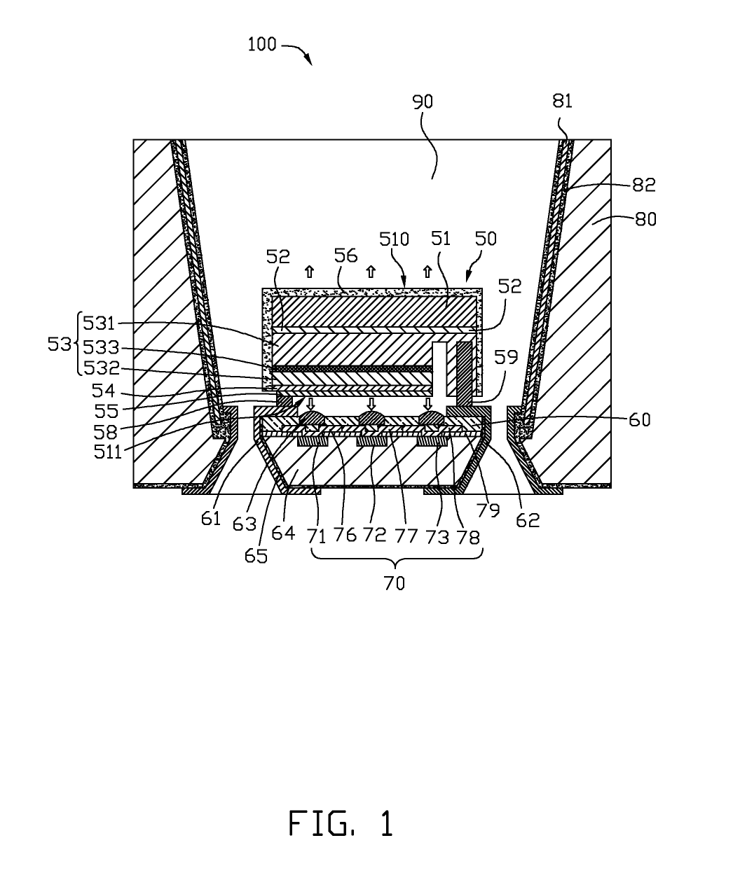

Referring to FIG. 1, an LED package 100 in accordance with a first embodiment includes an LED chip 50, a color sensor module 70, a transparent, electrically insulating layer 60 connected between the LED chip 50 and the color sensor module 70, a reflecting cup 80, and a sealant 90. Light from the LED chip 50 traveling through the transparent, electrically insulating layer 60 is detected by the color sensor module 70.

The LED chip 50 in this embodiment is a flip-chip. The LED chip 50 includes a substrate 51, a light emitting structure 53, a first electrode 58, and a second electrode 59. A buffer layer 52 is grown between the substrate 51 and the light emitting structure 53. The buffer layer 52 is made of GaN material in this embodiment. A p type contact layer 54 and a transparent layer 55 are arranged between the light emitting structure 53 and the first electrode 58. The substrate 51 is mounted on one side of the light emitting structure 53 away from the color sensor module 70. The light emitting structure 53, the p type contact layer 54, the transparent layer 55 sequentially extend from the substrate 51 to the sensor module 70. The LED chip 50 has a main light emitting surface 510 and a sub light emitting surface 511 opposite to the main surface 510. The main surface 510 is a surface of the LED chip 50 near the substrate 51. The sub surface 511 is a surface near the transparent layer 55.

The substrate 51 is a transparent plate. The substrate 51 is a high transmittance material, such as sapphire, SiC, GaN, ZnO. In this embodiment, the substrate 51 is sapphire.

The light emitting structure 53 includes a first semiconductor layer 531, a second semiconductor layer 532, and an active layer 533 between the first semiconductor layer 531 and the second semiconductor layer 532. The first semiconductor layer 531 is an n type GaN semiconductor layer. The second semiconductor layer 532 is a p type GaN semiconductor layer. The active layer 533 is a region of multiple quantum wells. A fluorescent powder layer 56 is arranged on a top surface and a side surface of the LED chip 50. The powder layer 56 is composed of yellow fluorescent powder. Understandably, the powder layer 56 can be made of one or more types of fluorescent powders. Furthermore, it is well known that fluorescent powder can be mixed with encapsulating material.

The first electrode 58 connects to a bottom of the transparent layer 55. The second electrode 59 connects to the first semiconductor layer 531. The first electrode 58 and the second electrode 59 are metal conductor electrodes.

The transparent, electrically insulating layer 60 can be made of epoxy, silicon, spin-on glass (SOG), polyimide, B-staged bisbenzocyclobutene (BCB), or glass. A first welding pad 61 arranged on the transparent, electrically insulating layer 60 is corresponding to the first electrode 58. A second welding pad 62 arranged on the transparent, electrically insulating layer 60 is corresponding to the second electrode 59. The first welding pad 61 and the second welding pad 62 respectively connect to the external circuit. The first welding pad 61 connects to the first electrode 58 and the second welding pad 62 connects to the second electrode 59 by eutectic method.

The color sensor module 70 includes color filter layers arranged on one side surface of the transparent, electrically insulating layer 60 away from the LED chip 50, a reflection layer 79, and a color detector (not labeled). The color filter layers in this embodiment are a red color filter layer 76, a green color filter layer 77, and a blue color filter layer 78. The red color filter layer 76, the green color filter layer 77, and the blue color filter layer 78 are mutually parallel and coplanar. The red color filter layer 76, the green color filter layer 77, and the blue color filter layer 78 each include a periphery portion (not labeled) embedded in the transparent, electrically insulating layer 60 and a central portion (not labeled) protruding downwardly out of the transparent, electrically insulating layer 60.

The reflection layer 79 is arranged on one side surface of the transparent, electrically insulating layer 60 away from the LED chip 50 and parallel to the color filter layers. The reflection layer 79 covers the transparent, electrically insulating layer 60 and the periphery portions of the red color filter layer 76, the green color filter layer 77, and the blue color filter layer 78. The reflection layer 79 is made of metal and prevents the light from the LED chip 50 from going through the color filter layers, except for the central protrusion portions thereof.

The color detector in this embodiment is a back side illumination detector including a red color light detector 71, a green color light detector 72, and a blue color light detector 73. The red detector 71, the green detector 72, and the blue detector 73 arranged on one side surface of the color filter layers away from the LED chips 50 are respectively corresponding to bottoms of the red color filter layer 76, the green color filter layer 77, and the blue color filter layer 78. The red detector 71, the green detector 72, and the blue detector 73 are received in a silicon plate 64. A wire connected to an external driving circuit (not shown) is arranged in the silicon plate 64. The red detector 71, the green detector 72, and the blue detector 73 respectively detects intensities of light from the LED chip 50 respectively traveling through the red color filter layer 76, the green color filter layer 77, and the blue color filter layer 78. Thus, the driving circuit can exert control according to the intensities of the three different colored lights. The color sensor module 70 can detect any variations in color temperature or light intensity from the LED chip 50, which may occur due to the weakening of the LED chip 50. Thus, the driving circuit can modify electrical parameters in order to stabilize intensity and the color temperature of the LED chip 50. The red detector 71, the green detector 72, and the blue detector 73 are photoelectric diodes.

A plurality of lenses 63 are arranged on one side surface of the transparent, electrically insulating layer 60 near the LED chips 50. Each lens 63 respectively on the red color filter layer 76, the green color filter layer 77, and the blue color filter layer 78 converges light through the red color filter layer 76, the green color filter layer 77, and the blue color filter layer 78. Thus, light entering into the red detector 71, the green detector 72, and the blue detector 73 is enhanced.

Understandably, the lens 63, and the color filter layers are directly fixed on the color detector. The first welding pad 61 and the second welding pad 62 are arranged on one side of the silicon plate 64. An insulating layer 65 is arranged between the silicon plate 64, the first welding pad 61 and the second welding pad 62. The reflecting cup 80 and the silicon plate 64 are integrally formed as a single piece in this embodiment. The first welding pad 61 and the second welding pads 62 are formed by filling metal into holes of the silicon plate 64. A reflection layer 81 is arranged on the inner surface of the reflecting cup 80 toward the LED chip 50. The reflection layer 81 is a metal layer. The insulating layers 82 are arranged between the reflecting cup 80 and the reflection layer 81, and over an inner surface of the reflection layer 81. Such an arrangement avoids the reflecting layer 81 from directly electrically connecting the first welding pads 61 and the second welding pads 62 whereby a possible short circuit therebetween is prevented.

Understandably, the LED chip 50 can be a low power LED, a high power LED, an AC LED, a high voltage LED, an AC high Voltage LED or a multichip LED. Light form the LED chip 50 can be a monochromatic light, such as a red light. Therefore, the LED chip 50 can be a red LED chip arranged over the color filter layers, and the color detectors can be red color light detectors.

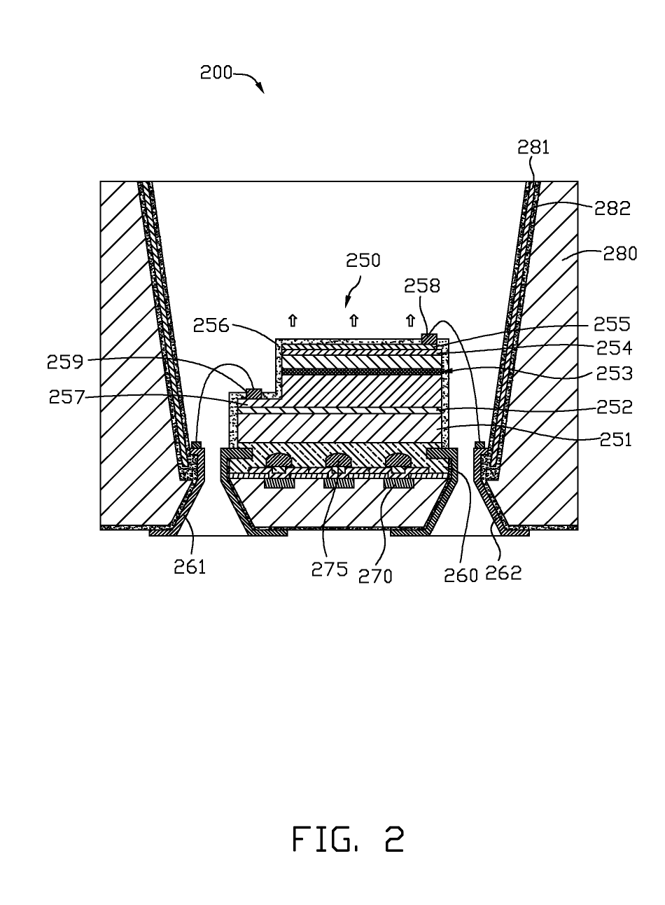

Referring to FIG. 2, an LED package 200 in accordance with a second embodiment includes an LED chip 250, a color sensor module 270, a transparent, electrically insulating layer 260 connected between the LED chip 250 and the sensor module 270, and a reflecting cup 280. The second embodiment differs from the first embodiment only in that the LED package 200 further includes a normal standard electrode of the LED chip 250.

The LED chip 250 includes a substrate 251 connected to the transparent, electrically insulating layer 260, a buffer layer 252, a light emitting structure 253, a p type semiconductor contact layer 254, a transparent conductor layer 255, an n type semiconductor contact layer 257, a first electrode 258 connected to the conductor layer 255, a second electrode 259 connected to the n type semiconductor contact layer 257. The first electrode 258 and the second electrode 259 respectively connect to a second welding pad 262 and a first welding pad 261 by wires (not labeled).

A fluorescent powder layer 256 is arranged on a top surface and a side surface of the LED chip 250. The layer 256 comprises yellow fluorescent powder. The lens 275 arranged inside the transparent, electrically insulating layer 260 corresponds to the sensor module 270. The reflecting cup 280 includes a reflection layer 281 facing the LED chip 250 and an insulating layer 282.

A part of the light from the LED chip 250 emits down through the buffer layer 252, the substrate 251, the transparent, electrically insulating layer 260 and the lens 275 to the sensor module 270. The intensities and the color temperature of the LED chip 250 detected by the sensor module 270 feed back to the driving circuit. When the detected value exceeds the predetermined value, the intensities and color temperature of the LED chip 250 are adjusted by controlling the circuit.

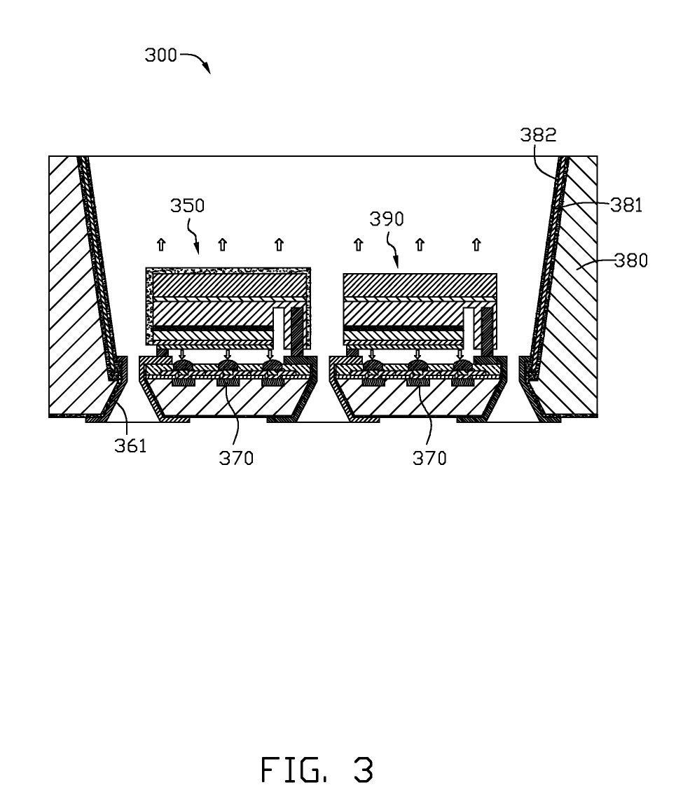

Referring to FIG. 3, an LED package 300 in accordance with a third embodiment includes a first LED chip 350, a second LED chip 390, two color sensor modules 370 respectively corresponding to the first LED chip 350 and the second LED chip 390. The yellow fluorescent powder is coated on the first LED chip 350, which emits blue light. The second LED chip 390 emits red light. Light from the first LED chip 350 and the second LED chip 390 is reflected by the reflection layer 381 of the reflecting cup 380. The sensor modules 370 detect the intensities of light from the first LED chip 350 and the second LED chip 390. Thus, the driving circuit can control the intensities and the color temperature of light from the LED package 300 according to signals of the sensor modules 370. Understandably, the second LED chip 390 can emit red light, and the color sensor module 390 can be a red color light detector.

While the disclosure has been described by way of example and in terms of exemplary embodiment, it is to be understood that the disclosure is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A light emitting diode package, comprising: at least one LED chip, at least one color sensor module, and a reflecting cup around the at least one LED chip, the at least one LED chip having a main light emitting surface and a sub light emitting surface opposite to the main surface, wherein the color temperature of at least one LED chip is adjustable according to intensities of light from the sub surface of the at least one LED chip detected by the at least one color sensor module.

2. The light emitting diode package of claim 1, wherein the at least one color sensor module includes a color filter layer, and a color detector, the light from the sub surface of the at least one LED chip traveling through the color filter layer and detected by the color detector.

3. The light emitting diode package of claim 2, wherein the at least one color sensor module further includes a reflection layer arranged parallel to the color filter layer.

4. The light emitting diode package of claim 1, wherein the at least one color sensor module further includes a lens corresponding to the color detector.

5. The light emitting diode package of claim 1, wherein the at least one LED chip is a low power LED, a high power LED, an AC LED, a high voltage LED, an AC high Voltage LED, or a multichip LED.

6. The light emitting diode package of claim 1, wherein a metal reflection layer is arranged on the reflecting cup, and an insulating layer is arranged between the metal reflection layer and the reflecting cup.

7. The light emitting diode package of claim 6, wherein the at least one color sensor module is arranged on a silicon plate, and the silicon plate and reflecting cup are integrally formed as a monolithic piece.

8. The light emitting diode package of claim 7, wherein the at least one LED chip includes a first electrode, a second electrode, a first welding pad electrically connected to the first electrode, and a second welding pad electrically connected to the second welding pad, and the insulating layer is arranged between the first welding pad, the second welding pad, and the silicon plate.

9. The light emitting diode package of claim 1, wherein the at least one LED chip includes fluorescent powders over an outer surface thereof.

10. A light emitting diode package comprising:
an LED chip having an upper major light emitting surface and a lower sub light emitting surface, light generated by the LED chip radiating from both the major and sub light emitting surfaces;
a transparent, electrically insulating layer below the lower sub light emitting surface of the LED chip; and
at least one light detector located below the transparent, electrically insulating layer for detecting intensity of the light from the sub light emitting surface of the LED chip.

11. The light emitting diode package of claim 10 further comprising a reflection layer between the at least one light detector and the transparent, electrically insulating layer, the reflection layer defining a void portion through which the light from the sub light emitting surface of the LED chip travels downwardly through the reflection layer to the at least one light detector.

12. The light emitting diode package of claim 11 further comprising a lens through which the light from the sub light emitting surface of the LED chip travels before it reaches the at least one light detector.

13. The light emitting diode package of claim 12, wherein the lens is in the transparent, electrically insulating layer.

14. The light emitting diode package of claim 11 further comprising at least one color filter layer between the transparent, electrically layer and the reflection layer, the at least one color filter layer having a protrusion downwardly extending into the void portion defined by the reflection layer.

15. The light emitting diode package of claim 14, wherein the at least one color filter layer comprises a periphery portion around the protrusion, the periphery portion being embedded in the transparent, electrically insulating portion.

16. The light emitting diode package of claim 14, wherein the at least one color filter layer includes three color filter layers which are respectively green color filter layer, blue color filter layer and red color filter layer and the at least one light detector includes three light detectors respectively corresponding to the three color filter layers.
